(19) United States
(12) Patent Application Publication
(10) Pub. No.: US 2025/0118590 A1
(43) Pub. Date: Apr. 10, 2025

(54) APPARATUS AND METHODS FOR MAINTAINING VACUUM CHECKING FORCE ON SEMICONDUCTOR SUBSTRATES UNDER ABNORMAL SEALING CONDITIONS

(71) Applicant: Axcelis Technologies, Inc., Beverly, MA (US)

(72) Inventor: Michael F. Leahy, Leicester, MA (US)

(21) Appl. No.: 18/910,385

(22) Filed: Oct. 9, 2024

Related U.S. Application Data
(60) Provisional application No. 63/588,815, filed on Oct. 9, 2023.

(51) Int. Cl. H01L 21/683; H01L 21/67

(52) U.S. Cl. CPC H01L 21/6838; H01L 21/67288

(57) ABSTRACT

In some embodiments, the present disclosure relates to workpiece handling system. The workpiece handling system includes a vacuum workpiece handler having a surface configured to receive a semiconductor workpiece. The surface has edges that form a plurality of vacuum suction holes along the surface. A plurality of vacuum conduits are respectively coupled to the plurality of vacuum suction holes, and a shared vacuum plenum is coupled to the plurality of vacuum conduits. The plurality of vacuum conduits are arranged between the shared vacuum plenum and the plurality of vacuum suction holes. A restrictor is configured to independently vary communication of the plurality of vacuum conduits between the shared vacuum plenum and the plurality of vacuum suction holes. The restrictor includes a plurality of self-regulated passive restricting units.

### REFERENCE TO RELATED APPLICATION

This Application claims the benefit of U.S. Provisional Application No. 63/588,815, filed on Oct. 9, 2023, the contents of which are incorporated by reference in their entirety.

### FIELD

The present invention relates generally to workpiece handling systems and processes, and more specifically to a system and method for preventing vacuum failure between a vacuum workpiece handler and a semiconductor workpiece.

### BACKGROUND

During integrated chip fabrication, many processing operations are performed on a semiconductor workpiece (e.g., wafer). When performing the processing operations and/or moving a semiconductor workpiece between processing tools, a semiconductor workpiece may be held at a fixed position with respect to a workpiece handler. There are a number of different ways that a workpiece handler can hold onto a semiconductor workpiece. One of the most common ways is by using a vacuum. By using a vacuum to hold onto a semiconductor workpiece, a vacuum workpiece handler can grip the semiconductor workpiece along a handling-side of the semiconductor workpiece so as to mitigate damage to a processing-side of the semiconductor workpiece that is being processed.

### BRIEF DESCRIPTION OF THE DRAWINGS

FIG. 1 illustrates some embodiments of a vacuum workpiece handling system comprising a restrictor configured to selectively restrict communication to one or more vacuum suction holes.

FIGS. 2A-2B illustrate some additional embodiments of a vacuum workpiece handling system comprising a restrictor configured to selectively restrict communication to one or more vacuum suction holes.

FIG. 3 illustrates some embodiments of a vacuum workpiece handling system comprising a restrictor including a plurality of active restricting units configured to selectively restrict communication to one or more vacuum suction holes.

FIGS. 4A-4C illustrate some embodiments of a workpiece handling system comprising a restrictor including a plurality of passive restricting units configured to selectively restrict communication to one or more vacuum suction holes.

FIG. 5 illustrates some additional embodiments of a workpiece handling system comprising a restrictor including a plurality of passive restricting units configured to selectively restrict communication to one or more vacuum suction holes.

FIGS. 6A-6B illustrate some additional embodiments of a vacuum workpiece handling system comprising a vacuum end-effector including a restrictor configured to selectively restrict communication to one or more vacuum suction holes.

FIGS. 7A-7B illustrate some additional embodiments of a vacuum workpiece handling system comprising a vacuum chuck including a restrictor configured to selectively restrict communication to one or more vacuum suction holes.

FIGS. 8-12 illustrate additional views corresponding to some embodiments of method of operating a disclosed vacuum workpiece handling system comprising a restrictor configured to selectively restrict communication to one or more vacuum suction holes.

FIG. 13 illustrates some embodiments of method of operating a disclosed vacuum workpiece handling system to selectively restrict communication to one or more vacuum suction holes.

### DETAILED DESCRIPTION

The present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, or other physical or functional units shown in the drawings or described herein could also be implemented by an indirect connection or coupling. Furthermore, it is to be appreciated that functional blocks or units shown in the drawings may be implemented as separate features or components in one embodiment, and may also or alternatively be fully or partially implemented in a common feature or component in another embodiment.

Modern-day integrated chips are formed by complex fabrication processes that perform a plurality of processes on a semiconductor workpiece. The processes may include implantation processes, etching processes, deposition processes, and/or the like. The different processes are performed by different fabrication tools. During fabrication, a semiconductor workpiece is moved between the different fabrication tools. Vacuum workpiece handling systems are often used to transport semiconductor workpieces between different fabrication tools and/or workpiece storage units (e.g., wafer cassettes, FOUPs, and/or the like).

A vacuum workpiece handling system may comprise a vacuum workpiece handler (e.g., a vacuum end-effector coupled to a robotic arm) having a surface configured to hold a semiconductor workpiece. The surface includes a plurality of vacuum suction holes that are in communication with a vacuum source. When the surface is brought into contact with a semiconductor workpiece, suction forces at the plurality of vacuum suction holes will hold the semiconductor workpiece at a fixed position with respect to the surface. The vacuum workpiece handler may subsequently move, so as to transfer the semiconductor workpiece.

The plurality of vacuum suction holes are typically designed to seal against a flat surface of a semiconductor workpiece. However, semiconductor workpieces may become bowed (e.g., warped) during processing. A bowed semiconductor workpiece will have an uneven (e.g., non-planar) handling surface that may preclude all of the vacuum suction holes on a surface of semiconductor vacuum workpiece handler from making contact with the semiconductor workpiece. The vacuum suction holes that do not make contact with the semiconductor workpiece may form an inadequate seal (e.g., a leak) between the surface and the semiconductor workpiece.

It has been appreciated that silicon carbide (SiC) workpieces tend to have a higher susceptibility to bowing (e.g., due to manufacturing methods and/or stress in the crystal lattice) than pure silicon workpieces. The larger bow may cause a vacuum suction hole of a vacuum workpiece handler to fail to maintain an adequate seal. A leaking vacuum suction hole may compromise an entire vacuum system (e.g., including non-leaking vacuum suction holes) of a vacuum workpiece handler, and cause a semiconductor workpiece to be inadequately secured to the surface of the vacuum workpiece handler. Inadequately securing a semiconductor workpiece to a surface of a vacuum workpiece handler can result in the semiconductor workpiece being dropped and/or damaged by the vacuum workpiece handler.

In some embodiments, the present disclosure relates to a workpiece handling system that is configured to mitigate an effect of one or more compromised vacuum suction holes by varying communication (e.g., decreasing fluid communication) between a compromised vacuum suction hole and a shared vacuum system. The workpiece handling system may comprise a vacuum workpiece handler having a surface configured to receive a semiconductor workpiece. The surface comprises edges that form a plurality of vacuum suction holes along the surface. A plurality of vacuum conduits are respectively coupled to the plurality of vacuum suction holes, and a shared vacuum plenum is coupled to the plurality of vacuum conduits. A restrictor is configured to independently vary communication along the plurality of vacuum conduits between the shared vacuum plenum and the plurality of vacuum suction holes. By independently varying communication between the shared vacuum plenum and the plurality of vacuum suction holes, fluid communication between a compromised vacuum suction hole and the shared vacuum plenum can be mitigated, so that the comprised vacuum suction hole does not negatively impact an overall ability of the workpiece handling system to hold a semiconductor workpiece.

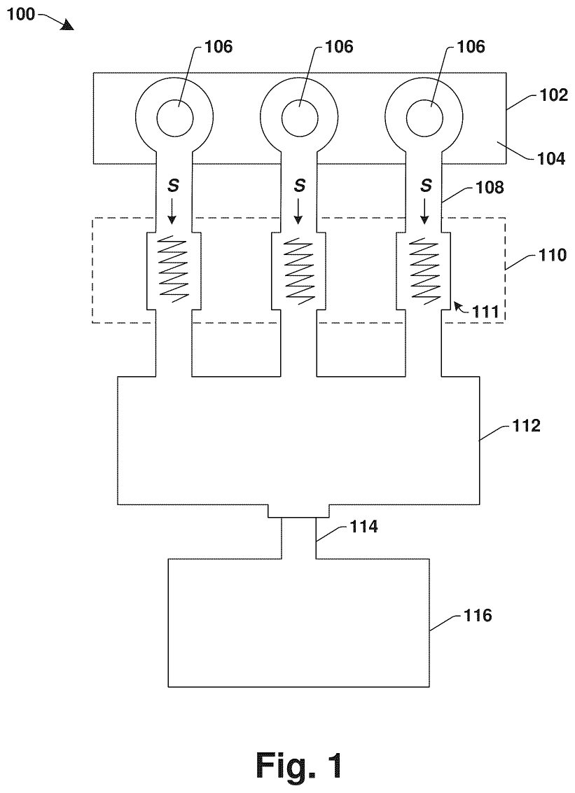

FIG. 1 illustrates some embodiments of a vacuum workpiece handling system 100 comprising a restrictor configured to selectively restrict communication to one or more vacuum suction holes.

The vacuum workpiece handling system 100 comprises a vacuum workpiece handler 102 comprising a surface 104 configured to receive a semiconductor workpiece. The surface 104 comprises a plurality of edges that form a plurality of vacuum suction holes 106 arranged along the surface 104. In some embodiments, the plurality of vacuum suction holes 106 may be separated from one another by the surface 104. In some embodiments, the plurality of vacuum suction holes 106 include all of the vacuum suction holes within the surface 104.

The plurality of vacuum suction holes 106 are respectively coupled to one of a plurality of vacuum conduits 108. The plurality of vacuum conduits 108 are further coupled to a shared vacuum plenum 112. The plurality of vacuum conduits 108 are upstream of the shared vacuum plenum 112, such that the plurality of vacuum conduits 108 separately extend between the shared vacuum plenum 112 and a respective one of the plurality of vacuum suction holes 106. The shared vacuum plenum 112 is further coupled to a vacuum source 116 by way of a vacuum source conduit 114. During operation, the vacuum source 116 is configured to reduce a pressure within the shared vacuum plenum 112. By reducing a pressure within the shared vacuum plenum 112, suction forces S are generated at respective ones of the plurality of vacuum suction holes 106. The suction forces S point inward towards the shared vacuum plenum 112.

A restrictor 110 is disposed along the plurality of vacuum conduits 108. The restrictor 110 is configured to independently vary communication (e.g., fluid communication) between one or more of the plurality of vacuum suction holes 106 and the shared vacuum plenum 112. By independently varying communication between one or more of the plurality of vacuum suction holes 106 and the shared vacuum plenum 112, the restrictor 110 is able to independently modify a strength of a corresponding suction force S associated with respective ones of the plurality of vacuum suction holes 106. For example, the restrictor 110 may vary (e.g., reduce) a suction force of a first one of the plurality of vacuum suction holes 106 without varying (e.g., reducing) suction forces associated with other ones of the plurality of vacuum suction holes 106.

In some embodiments, the restrictor 110 may comprise or be a plurality of separate restricting units 111 configured to independently vary communication between one of the plurality of vacuum suction holes 106 and the shared vacuum plenum 112. In some embodiments, the restrictor 11 may comprise a passive restrictor having a plurality of separate restricting units 111 respective comprising passive restricting units that are configured to automatically vary communication between one of the plurality of vacuum suction holes 106 and the shared vacuum plenum 112 in response to formation of a leak (e.g., a vacuum suction hole that fails to adequately seal with a semiconductor workpiece). In various embodiments, the passive restricting units may comprise restricting units having a fixed-geometry structure, restricting units having moving parts that are self-regulated (e.g., using pneumatics), and/or the like. By using passive restricting units that are self-regulated, communication with compromised vacuum suction holes can be varied without control units, thereby allowing for a low-cost and low-maintenance system that is easy to operate and integrate into production.

In other embodiments, the plurality of separate restricting units 111 may comprise active restricting units that are configured to vary communication between one of the plurality of vacuum suction holes 106 and the shared vacuum plenum 112 by generating a mechanical motion in response to a leak being detected by a sensor.

By varying communication between one of the plurality of vacuum suction holes 106 and the shared vacuum plenum 112, the restrictor 110 is able to mitigate a negative effect of a comprised vacuum suction hole. For example, if a first vacuum suction hole of the plurality of vacuum suction holes 106 fails to properly seal (e.g., is not completely covered by a semiconductor workpiece along all edges of the first vacuum suction hole), the restrictor 110 can restrict communication with the first vacuum suction hole so as to prevent the leak from effecting other ones of the plurality of vacuum suction holes 106 (e.g., preventing a pressure lose in the shared vacuum plenum 112). Therefore, the restrictor 110 is able to prevent a compromised one of the plurality of vacuum suction holes 106 from causing a vacuum failure over an entirety of the vacuum workpiece handling system 100.

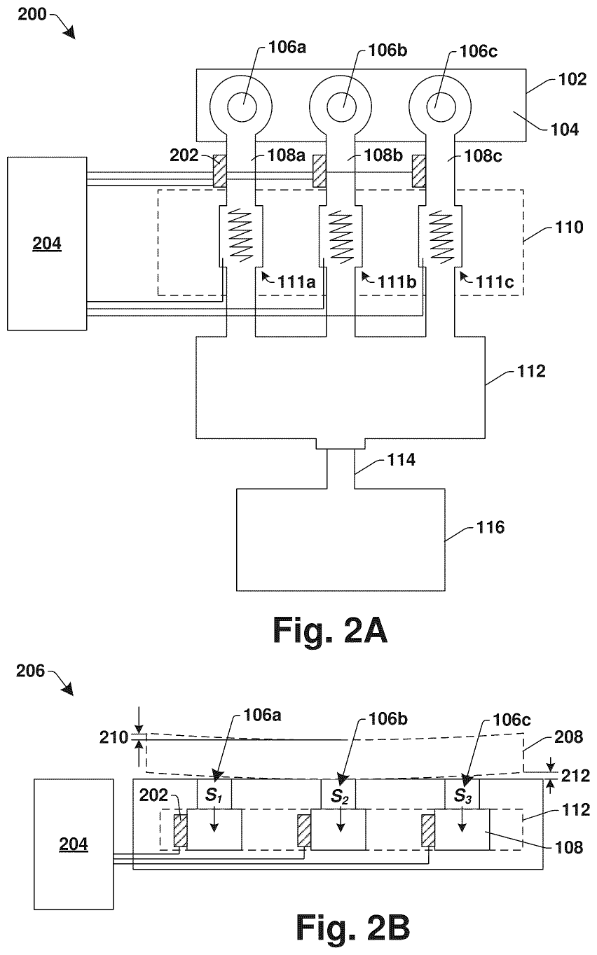

FIG. 2A illustrates some additional embodiments of a vacuum workpiece handling system 200 comprising a restrictor configured to selectively restrict communication to one or more vacuum suction holes.

The vacuum workpiece handling system 200 comprises a vacuum workpiece handler 102 comprising a surface 104 configured to receive a semiconductor workpiece. In some embodiments, the vacuum workpiece handler 102 comprises an end-effector configured to be coupled to a robotic arm of a robot (e.g., an EFEM (equipment front end module)). A plurality of vacuum suction holes 106a-106c are arranged within the surface 104. The plurality of vacuum suction holes 106a-106c are coupled to respective ones of a plurality of vacuum conduits 108a-108c. For example, vacuum suction hole 106a is coupled to vacuum conduit 108a, vacuum suction hole 106b is coupled to vacuum conduit 108b, etc.

The plurality of vacuum conduits 108a-108c are further coupled to a shared vacuum plenum 112. In some embodiments, the plurality of vacuum conduits 108a-108c extend outward from a sidewall of the shared vacuum plenum 112. The shared vacuum plenum 112 is further coupled to a vacuum source 116 by way of a vacuum source conduit 114. Because each of the plurality of vacuum suction holes 106a-106c are coupled to a separate one of the plurality of vacuum conduits 108a-108c, a separate path exists between each of the plurality of vacuum suction holes 106a-106c and the shared vacuum plenum 112.

A restrictor 110 is disposed along the plurality of vacuum conduits 108a-108c. In some embodiments, the restrictor 110 comprises a plurality of restricting units 111a-111c. The plurality of restricting units 111a-111c are respectively configured to vary fluid communication of a single one of the plurality of vacuum conduits 108a-108c between the shared vacuum plenum 112 and a single one of the plurality of vacuum suction holes 106a-106c. In various embodiments, the restricting units 111a-111c may comprise a valve, a diaphragm, and/or the like.

In some embodiments, one or more sensors 202 are configured to measure data associated with one or more of the plurality of vacuum suction holes 106a-106c. In some embodiments, the one or more sensors 202 are in communication with the plurality of vacuum conduits 108a-108c. In various embodiments, the one or more sensors 202 may be configured to measure a change in a pressure, a flow rate, and/or the like within a corresponding one of the plurality of vacuum conduits 108a-108c.

In some embodiments, a controller 204 is configured to receive the data from the one or more sensors 202. Based upon the received data, the controller 204 is configured to detect a compromised vacuum suction hole (e.g., a leak of a sealing area around a vacuum suction hole). In some embodiments, the controller 204 may be coupled to the restrictor 110. In such embodiments, the controller 204 is configured to independently control operation of the plurality of restricting units 111a-111c. For example, in response to a detected failure of a sealing area associated with a compromised vacuum suction hole, the controller 204 is configured to generate a signal that is provided to one of the plurality of restricting units 111a-111c associated with a vacuum conduit associated with the compromised vacuum suction hole. The signal causes the restricting unit to selectively restrict fluid communication between the shared vacuum plenum 112 and the compromised vacuum suction hole.

FIG. 2B illustrates a cross-sectional view 206 illustrating operation of the disclosed vacuum workpiece handling system.

As shown in cross-sectional view 206, a semiconductor workpiece 208 may be brought into contact with a surface 104 of the vacuum workpiece handler 102 that is in an ambient environment. The semiconductor workpiece 208 comprises a handling-side configured to contact the surface 104 and a processing-side opposing the handling side. The ambient environment may have a first pressure that is larger than a second pressure within the shared vacuum plenum 112. The difference between the first pressure and the second pressure generates suction forces S₁-S₃, which extend inward into the plurality of vacuum suction holes 106a-106c.

In some embodiments, the semiconductor workpiece 208 may be bowed (e.g., bent or warped) to have a bow 210 (e.g., a vertical variance between different points along an upper surface of the semiconductor workpiece 208). In some embodiments, the semiconductor workpiece 208 may comprise semiconductor workpiece that has been previously acted upon by a fabrication process (e.g., an etching process, a deposition process, an ion implantation process, and/or the like). In various embodiments, the semiconductor workpiece 208 may comprise a silicon carbide workpiece, a silicon workpiece, or the like.

The plurality of vacuum suction holes 106a-106c within the surface 104 are configured to form a vacuum seal against a flat surface of the semiconductor workpiece 208. However, the bow 210 of the semiconductor workpiece 208 may cause a part of the semiconductor workpiece 208 to be vertically separated from the surface 104 by a non-zero distance 212, such that an entire lower surface of the semiconductor workpiece 208 does not contact the surface 104. Because one or more of the plurality of vacuum suction holes 106a-106c are not completely covered by the semiconductor workpiece 208, all of the plurality of vacuum suction holes 106 may be precluded from making an adequate seal with the surface 104 thereby resulting in one or more leaks in a vacuum system associated with the shared vacuum plenum 112.

The one or more sensors 202 may be configured to generate data that is used to detect a failure of a sealing area (e.g., a leak) associated with a vacuum suction hole. For example, the one or more sensors 202a-202c may generate data corresponding to the plurality of vacuum conduits 108a-108c. The data may be provided to the controller 204. Based upon the data, the controller 204 may determine that vacuum suction holes 106a and 106c have been compromised (e.g., vacuum suction holes 106a and 106c are not completely covered by the semiconductor workpiece 208). In response to the detected leaks, the controller 204 will generate signals that cause restricting units 111a and 111c to decrease fluid communication between the shared vacuum plenum 112 and vacuum suction holes 106a and 106c. In some embodiments, the restriction units may partially or completely isolate the shared vacuum plenum from vacuum suction holes 106a and 106c. The decreased fluid communication will reduce a suction forces S₁ and S₃ associated with vacuum suction holes 106a and 106c to prevent the leaks from causing failure of the entire vacuum workpiece handling system.

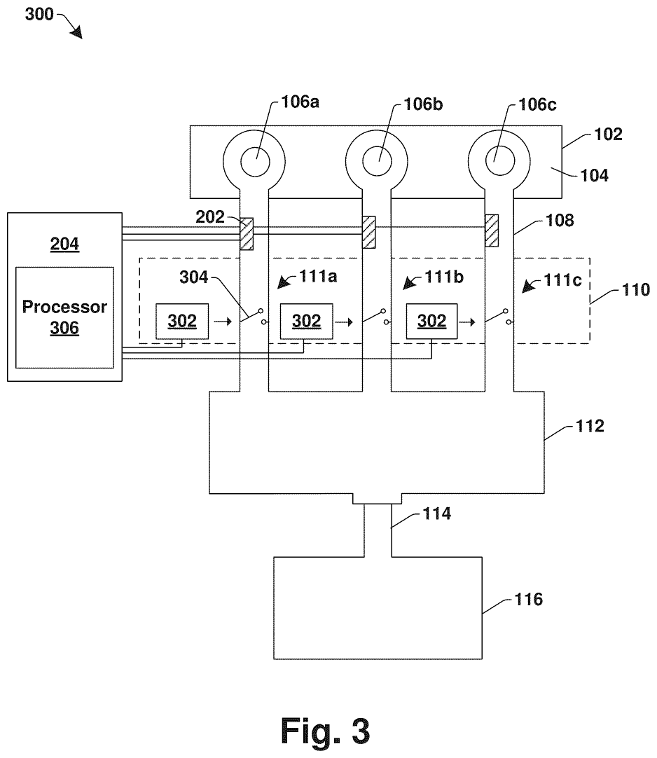

FIG. 3 illustrates some embodiments of a vacuum workpiece handling system 300 comprising a restrictor including a plurality of active restricting units configured to selectively restrict communication to one or more vacuum suction holes.

The vacuum workpiece handling system 300 comprises a vacuum workpiece handler 102 including a surface 104 configured to receive a semiconductor workpiece. A plurality of vacuum suction holes 106 are arranged along the surface 104. The plurality of vacuum suction holes 106 are coupled to respective ones of a plurality of vacuum conduits 108. The plurality of vacuum conduits 108 are further coupled to a shared vacuum plenum 112. In some embodiments, the plurality of vacuum conduits 108 respectively comprise fixed opposing sidewalls extending outward from the shared vacuum plenum 112. The fixed opposing sidewalls of neighboring ones of the plurality of vacuum conduits 108 may extend in parallel to one another for a non-zero run length. The shared vacuum plenum 112 is further coupled to a vacuum source 116 by way of a vacuum source conduit 114.

One or more sensors 202 are arranged in communication with the plurality of vacuum conduits 108. In some embodiments, the one or more sensors 202 may be disposed (partially or fully) within the plurality of vacuum conduits 108. The one or more sensors 202 are configured to generate data that is provided to a controller 204. From the data, the controller 204 is able to detect a leak associated with one or more of the plurality of vacuum suction holes 106. In various embodiments, the one or more sensors 202 may comprise a pressure sensor, a flow rate sensor, and/or the like. In some embodiments, the controller 204 may comprise a processing unit 306 (e.g., a central processing unit including one or more transistor devices configured to operate computer code to achieve a result, a microcontroller, or the like).

Upon detecting a leak, the controller 204 is configured to provide a signal to a restrictor 110 that is in communication with the plurality of vacuum conduits 108. In some embodiments, the restrictor 110 comprises a plurality of restricting units 111. The plurality of restricting units 111 are configured to control fluid communication between a corresponding one of the plurality of vacuum suction holes 106 and the shared vacuum plenum 112. In some embodiments, the plurality of restricting units 111 may respectively comprise an actuator 302 and a blocking member 304. The actuator 302 is configured to selectively change a physical position of a blocking member 304 within a corresponding vacuum conduit 108. By changing the physical position of the blocking member 304, the actuator 302 is able to change (e.g., reduce) a cross-sectional area of the corresponding vacuum conduit. For example, in some embodiments the actuator 302 may rotate a blocking member 304 to reduce a cross-sectional area of a corresponding vacuum conduit. In other embodiments, the actuator 302 may change a distance to which a blocking member 304 extends into a corresponding vacuum conduit to reduce a cross-sectional area of the corresponding vacuum conduit. In some embodiments, the plurality of restricting units 111 may be configured to vary a cross-sectional area of a vacuum conduit without varying a cross-sectional area of a neighboring vacuum conduit.

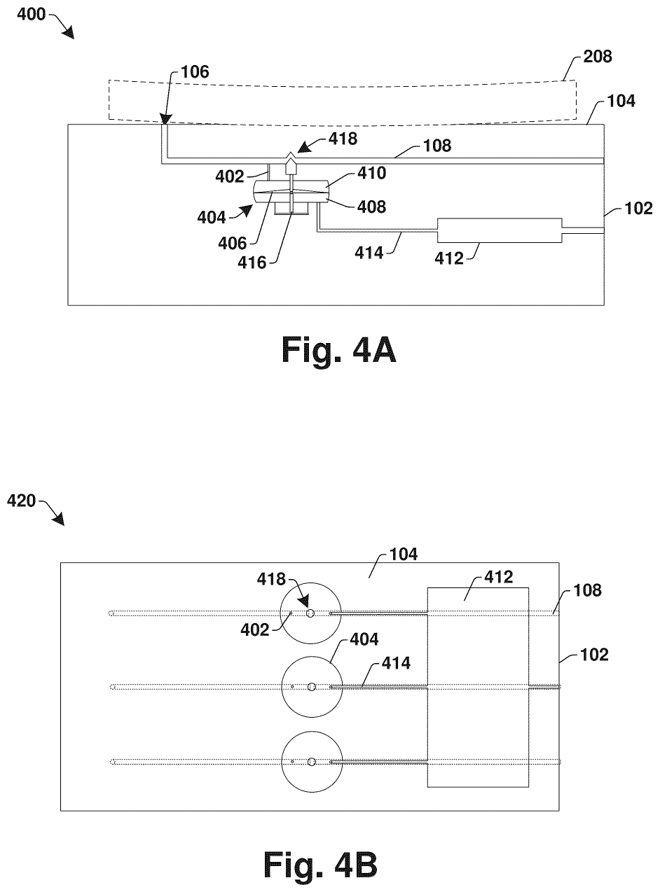

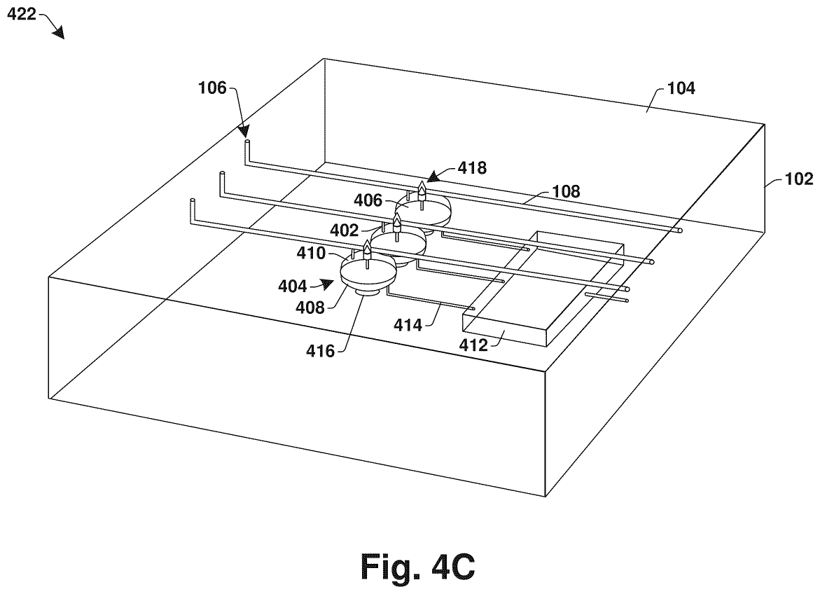

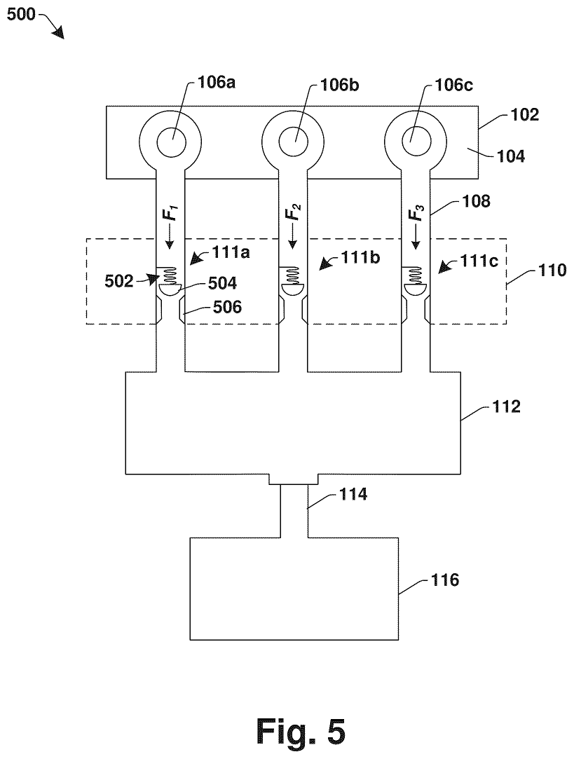

FIGS. 4A-4C and 5 illustrate some embodiments of vacuum workpiece handling systems comprising a restrictor including a plurality of passive restricting units. The plurality of passive restricting units are self-regulated restricting units, which are configured to selectively restrict communication to one or more vacuum suction holes. It will be appreciated that the plurality of passive restricting units shown in FIGS. 4A-4C and 5 are non-limiting examples of possible passive restricting units. However, one of ordinary skill in the art will appreciate that the plurality of passive restricting units disclosed herein are not limited to those shown in FIGS. 4A-4C and 5.

FIG. 4A illustrates a cross-sectional view 400 of some embodiments of a vacuum workpiece handler comprising a plurality of passive restricting units including a diaphragm valve.

As shown in cross-sectional view 400, the vacuum workpiece handler comprises a plurality of vacuum conduits 108 coupled to a plurality of vacuum suction holes 106 within a surface 104 that is configured to receive a semiconductor workpiece 208. The plurality of vacuum conduits 108 are coupled to a pressure sampling port 402 (e.g., sampling tubes) that is connected to a sealing valve chamber 404. A diaphragm 406 is arranged within the sealing valve chamber 404. The diaphragm 406 separates a lower region 408 of the sealing valve chamber 404 from an upper region 410 of the sealing valve chamber 404. The lower region 408 is in communication with a reference pressure chamber 412 by way of a reference pressure conduit 414, while the upper region 410 is in communication with one of the plurality of vacuum conduits 108 by way of the pressure sampling port 402. A moveable assembly 416 is coupled to the diaphragm 406. The moveable assembly 416 is further coupled to a sealing valve 418 that is arranged within the plurality of vacuum conduits 108.

During operation, the sealing valve 418 is configured to move depending upon a pressure within a corresponding one of the plurality of vacuum conduits 108. For example, when a corresponding one of the plurality of the plurality of vacuum suction holes 106 seals properly, a pressure within the upper region 410 of the sealing valve chamber 404 is greater than or equal to a pressure within the lower region 408 of the sealing valve chamber 404 and the sealing valve 418 is kept in an open position. However, when a leak forms within the vacuum suction hole 106 (e.g., due to the semiconductor workpiece 208 not contacting the surface 104 along the vacuum suction hole 106), the pressure sampling port 402 will change a pressure within the upper region 410 of the sealing valve chamber 404. The change (e.g., decrease) in pressure within the upper region 410 of the sealing valve chamber 404 causes the diaphragm 406 to move (e.g., push up) and close the sealing valve 418, thereby automatically varying fluid communication between the vacuum suction hole 106 and a shared vacuum plenum (downstream of the vacuum conduit) in response to formation of the leak.

FIG. 4B illustrates a top-view 420 corresponding to the vacuum workpiece handler shown in the cross-sectional view 400 of FIG. 4A. As shown in top-view 420, the vacuum workpiece handler comprises three separate vacuum suction holes, which are respectively coupled to separate pressure sampling ports that are further coupled to separate sealing valve chambers and sealing valves. Because the separate vacuum holes are coupled to separate sealing valve chambers and sealing values, communication between the separate vacuum holes and a shared vacuum plenum (e.g., coupled to the separatee separate plurality of vacuum conduits) can be independently controlled for each vacuum hole.

FIG. 4C illustrates a three-dimensional view 422 corresponding to the vacuum workpiece handler shown in the cross-sectional view 400 of FIG. 4A and the top-view 420 shown in FIG. 4B.

FIG. 5 illustrates a top-view of some additional embodiments of a vacuum workpiece handling system 500 comprising a plurality of passive restricting units respectively including a diaphragm valve.

The vacuum workpiece handling system 500 comprises a plurality of vacuum suction holes 106 arranged within a surface 104 of a vacuum workpiece handler 102. A plurality of diaphragm valves are respectively disposed within a plurality of vacuum conduits 108 coupled to the plurality of vacuum suction holes 106. In some embodiments, the plurality of diaphragm valves 502 respectively comprise a diaphragm 504 arranged within a vacuum conduit 108 and coupled to an elastic element 506 (e.g., a spring). Under an acceptable flow rate and/or pressure, the diaphragm 504 is located at a first position within the vacuum conduit 108 that allows for air to flow past the diaphragm 504. For example, prior to bringing a semiconductor workpiece into contact with the surface 104 flow rates within the plurality of vacuum conduits 108 are insufficient to close the plurality of diaphragm valves 502 so that a suction force is present at each of the plurality of vacuum suction holes 106.

However, a compromised vacuum suction hole will cause the flow rate and/or the pressure to increase. This is because a semiconductor workpiece will block some of the plurality of vacuum suction holes 106, causing a flow rate associated with the compromised vacuum suction hole to increase. When the flow rate associated with the compromised vacuum suction hole exceeds a threshold, a force of air will push the diaphragm 504 downward into a narrow segment of the vacuum conduit 108. Because the narrow segment has a smaller cross-sectional area, the diaphragm 504 will block the narrow segment and automatically reduce fluid communication (e.g., isolate) between the compromised vacuum suction hole and a shared vacuum plenum 112 upon formation of a leak, thereby preventing the compromised vacuum suction hole from causing failure of the vacuum workpiece handling system 500.

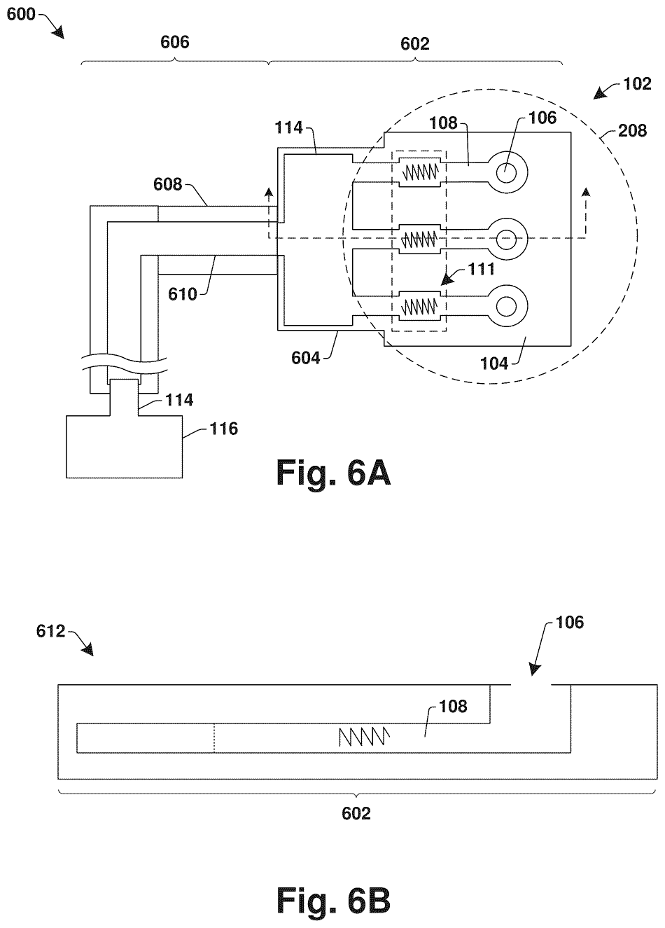

FIGS. 6A-6B illustrate some additional embodiments of a vacuum workpiece handling system comprising a vacuum workpiece handler including a vacuum end-effector having a restrictor configured to selectively restrict communication to one or more vacuum suction holes. FIG. 6A illustrates a top-view 600 of the workpiece handling system including a vacuum end-effector. FIG. 6B illustrates a cross-sectional view 612 of the vacuum end-effector.

As shown in top-view 600, the vacuum workpiece handling system comprises a vacuum workpiece handler 102 that is or includes a vacuum end-effector 602. The vacuum end-effector 602 is coupled to a robotic arm 608 of an EFEM 606. The vacuum end-effector 602 is configured to pick-up and hold a semiconductor workpiece 208 while the EFEM 606 is transferring the semiconductor workpiece 208. For example, the vacuum end-effector 602 may be configured to hold a semiconductor workpiece 208 while the EFEM 606 is transferring the semiconductor workpiece 208 between a workpiece holding unit (e.g., a wafer cassette, FOUP (front-opening unified pod), or the like) and a semiconductor processing tool (e.g., an etching system, a deposition system, an ion implantation system, or the like).

The vacuum end-effector 602 comprises an outer casing 604. The outer casing 604 comprises a coupler that is configured to couple the outer casing 604 to the robotic arm 608 along an interface. In various embodiments, the outer casing 604 may comprise or be one or more of a metal, a plastic, a polymer, or the like. A plurality of vacuum suction holes 106 extend through a surface 104 of the outer casing 604 that is configured to receive the semiconductor workpiece 208. The plurality of vacuum suction holes 106 are coupled to a plurality of vacuum conduits 108 that connect the plurality of vacuum suction holes 106 to a shared vacuum plenum 112.

The outer casing 604 surrounds at least a first part of the plurality of vacuum conduits 108. In some embodiments, the plurality of vacuum conduits 108, the shared vacuum plenum 112, and a plurality of restricting units 111 are housed within the outer casing 604 of the vacuum workpiece handler 102. In such embodiments, the shared vacuum plenum 112 is coupled to an EFEM conduit 610 that extends through the EFEM 606. In other embodiments (not shown), the outer casing 604 may surround the first part of the plurality of vacuum conduits 108, while a second part of the plurality of vacuum conduits 108 and the shared vacuum plenum 112 are disposed outside of the outer casing 604 (e.g., within the EFEM 606). In such embodiments, the plurality of vacuum conduits 108 extend through the interface between the outer casing 604 and the robotic arm 608.

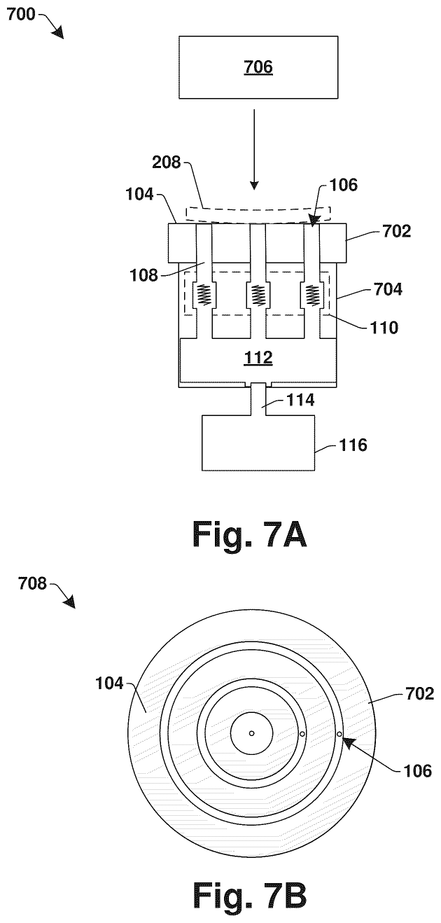

FIGS. 7A-7B illustrate some additional embodiments of a vacuum workpiece handling system comprising a vacuum workpiece handler including a vacuum chuck having a restrictor configured to selectively restrict communication to one or more vacuum suction holes. FIG. 7A illustrates a top-view 700 of the workpiece handling system. FIG. 7B illustrates a side-view 708 of the workpiece handling system.

As shown in top-view 700, the vacuum wafer handling system comprises a puck 702 disposed over a pedestal base 704. A plurality of vacuum suction holes 106 are arranged along a surface 104 of the puck 702 that is configured to receive a semiconductor workpiece 208 (e.g., a silicon carbide wafer). The plurality of vacuum suction holes 106 are coupled to separate ones of a plurality of vacuum conduits 108, which are further coupled to a shared vacuum plenum 112. In some embodiments, the separate vacuum conduits 108 may extend through the puck 702 to the shared vacuum plenum 112, which is located within the pedestal base 704.

In some embodiments, the puck 702 may comprise a rotatable puck that is in communication with an aligner sensor 706 configured to determine a proper alignment of the semiconductor workpiece 208. In some embodiments, the aligner sensor 706 may comprise an optical sensor that is configured to operate at a wavelength of radiation that passes through a silicon carbide substrate. However, due to devices on the silicon carbide substrate, the aligner sensor 706 may not operate properly unless the semiconductor workpiece 208 is properly aligned. Therefore, in some such embodiments, the puck 702 is configured to receive the semiconductor workpiece 208 and to hold the semiconductor workpiece 208 in place as the puck 702 is rotated to a proper alignment. In some embodiments, the shared vacuum plenum 112 and the plurality of vacuum conduits 108 may rotate along with the puck 702 around the vacuum source conduit 114.

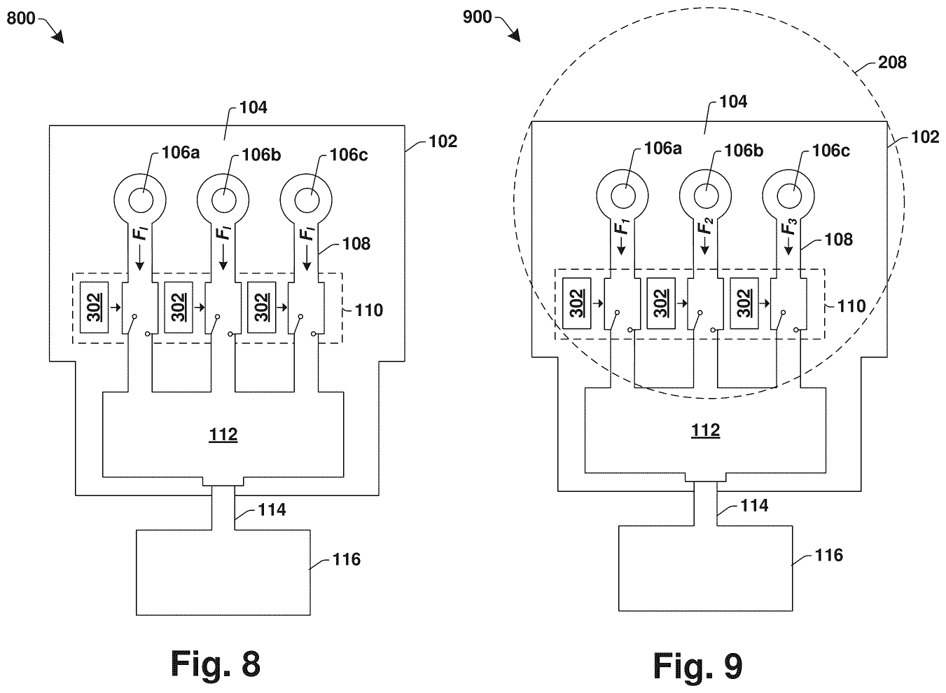

FIGS. 8-12 illustrate additional views 800-1200 corresponding to some embodiments of method of operating a disclosed vacuum workpiece handling system comprising a restrictor configured to selectively restrict communication to one or more vacuum suction holes.

As shown in top-view 800 of FIG. 8, a vacuum wafer handling system is operated to generate a plurality of suction forces at a plurality of vacuum suction holes 106a-106c disposed within a surface 104 of a vacuum workpiece handler 102 within an ambient environment. The plurality of suction forces may cause air to flow through a plurality of vacuum conduits 108 at a plurality of initial flow rates Fi, which are substantially equal to one another. In some embodiments, the plurality of suction forces may be generated by operating a vacuum source 116 to decrease a pressure within a shared vacuum plenum 112 that is coupled to the plurality of vacuum suction holes 106a-106c by way of the plurality of vacuum conduits 108. The ambient environment has a higher pressure than the shared vacuum plenum 112 so that air flows through the plurality of vacuum conduits 108 at the plurality of initial flow rates FI.

As shown in top-view 900 of FIG. 9, a semiconductor workpiece 208 is brought into contact with the surface 104 of the vacuum workpiece handler 102 so as to cover one or more of the plurality of vacuum suction holes 106a-106c. The plurality of suction forces are configured to hold the semiconductor workpiece 208 to the surface 104. In various embodiments, the semiconductor workpiece 208 may comprise a silicon carbide workpiece, a silicon workpiece, or the like. In some embodiments, the surface 104 of the vacuum workpiece handler 102 may be brought into contact with a handling side (e.g., a back-side) of the semiconductor workpiece 208.

In some embodiments, the semiconductor workpiece 208 may be bowed (e.g., warped) so that one or more of the plurality of vacuum suction holes 106a-106c are completely sealed by the semiconductor workpiece 208, while one or more of the plurality of vacuum suction holes 106a-106c are compromised (e.g., not completely sealed by the semiconductor workpiece 208 due to a space between the surface 104 and the semiconductor workpiece 208). The semiconductor workpiece 208 may have a flat surface that continuously contacts the surface 104 around a completely sealed vacuum hole, while the semiconductor workpiece 208 may have a bowed surface that contacts a part (but not all) of the surface 104 surrounding a compromised vacuum hole. For example, the semiconductor workpiece 208 may be warped so that the semiconductor workpiece is not brought into contact with the surface 104 around compromised vacuum suction hole 106a, resulting in a leak associated with compromised vacuum suction hole 106a.

The leak associated with the compromised vacuum suction hole 106a causes an imbalance between the plurality of flow rates. For example, flow rates F₂-F₃ within vacuum conduits coupled to properly sealed vacuum suction holes 106b-106c will be different than a flow rate F′₁ associated with a compromised vacuum suction hole 106a. This is because the properly sealed vacuum suction holes 106b-106c will not allow air from the ambient environment to enter into a corresponding vacuum conduit, while the compromised vacuum suction hole 106a will allow air from the ambient environment to enter into a corresponding vacuum conduit. In some embodiments, the imbalance between the plurality of flow rates F′₁, F₂, and F₃ may be generated when the semiconductor workpiece 208 is brought into contact with the surface 104 of the vacuum workpiece handler 102. In other embodiments, the imbalance between the plurality of flow rates F′₁, F₂, and F₃ may be generated concurrent with movement of the vacuum workpiece handler 102.

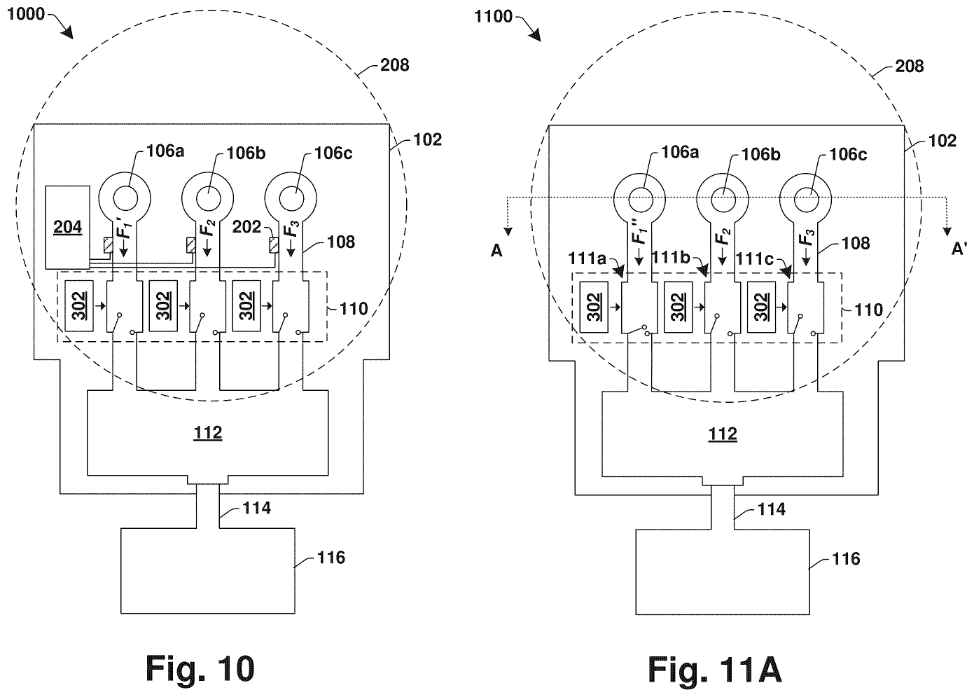

As shown in top-view 1000 of FIG. 10, in some embodiments one or more sensors 202 may be configured to measure data that is indicative of the imbalance between the plurality of flow rates F′₁, F₂, and F₃. In various embodiments, the data may comprise a flow rate, a pressure, and/or the like. The data is provided to a controller 204 that is configured to detect the imbalance between the plurality of flow rates F′₁, F₂, and F₃. In other embodiments, the one or more sensors may be omitted and passive restrictor units may be used to automatically vary (e.g., reduce) one or more of the plurality of flow rates F′₁, F₂, and F₃.

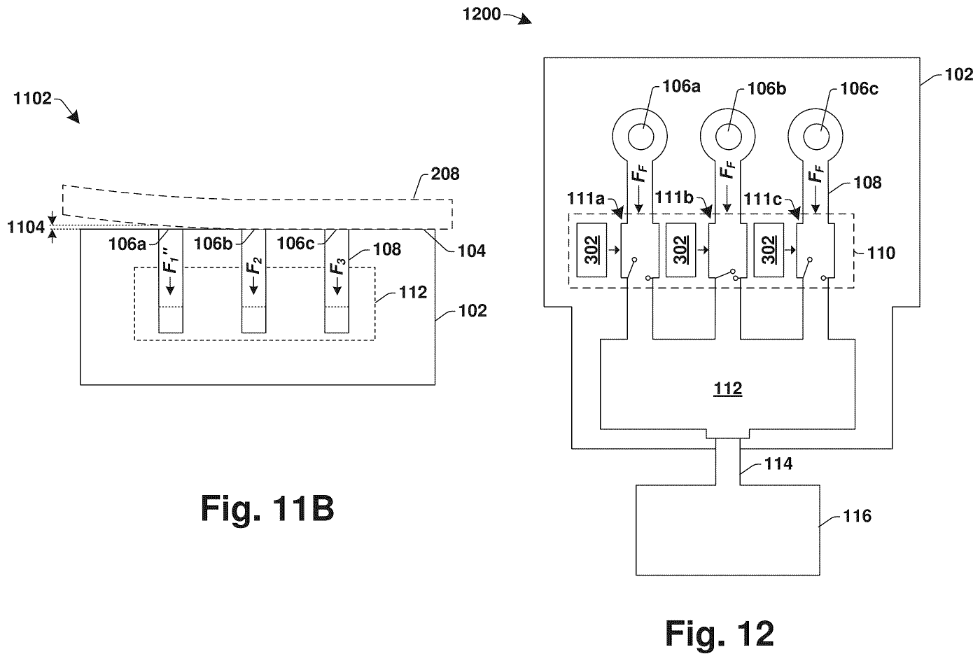

As shown in top-view 1100 of FIG. 11A, a restricting unit 111a associated with the compromised vacuum suction hole 106a is operated to vary fluid communication between the compromised vacuum suction hole 106a and the shared vacuum plenum 112. In some embodiments, varying fluid communication between the compromised vacuum suction hole 106a and the shared vacuum plenum 112 reduces a flow rate within the vacuum conduit 108 (e.g., to a value of F″₁<F′₁) and a suction associated with the compromised vacuum suction hole 106a so as to isolate (e.g., partially or fully) the compromised vacuum suction hole 106a from the shared vacuum plenum 112. For example, in some embodiments the restricting unit 111a may be configured to sever communication between the shared vacuum plenum 112 and the compromised vacuum suction hole 106a, so that a space between the surface 104 and the semiconductor workpiece 208 does not allow for leakage into the shared vacuum plenum 112. Isolating the compromised vacuum suction hole 106a from the shared vacuum plenum 112 prevents the compromised vacuum suction hole 106a from causing failure of the vacuum workpiece handler 102.

In some embodiments, the restricting unit 111a associated with the compromised vacuum suction hole 106a is configured to vary fluid communication between the compromised vacuum suction hole 106 and the shared vacuum plenum 112 by adjusting a cross-sectional area of one of the plurality of vacuum conduits 108 associated with the compromised vacuum suction hole 106a. In some embodiments, varying fluid communication between the compromised vacuum suction hole 106a and the shared vacuum plenum 112 will reduce an overall attractive force between the semiconductor workpiece 208 and the surface 104. However, the resulting overall attractive force is sufficient to prevent a total loss of grip between the semiconductor workpiece 208 and the surface 104 in spite of bowing of the semiconductor workpiece 208.

FIG. 11B illustrates a cross-sectional view 1102 taken along cross-sectional line A-A′ in FIG. 11A. As shown in cross-sectional view 1102, a space 1104 is present between the compromised vacuum suction hole 106a and the semiconductor workpiece 208. While the restricting unit (e.g., 111a of FIG. 11A) will reduce a flow rate within the one of the plurality of vacuum conduits 108 associated with the compromised vacuum suction hole 106a, it will not flatten a bowing of the semiconductor workpiece 208 but will rather reduce leakage into the shared vacuum plenum 112 by the compromised vacuum suction hole 106a. Therefore, the space 1104 will not compromise a vacuum within the shared vacuum plenum 112 and thus will allow for the vacuum workpiece handler 102 to maintain sufficient vacuum suction to hold the semiconductor workpiece 208 in spite of bowing of the semiconductor workpiece 208.

In some embodiments (not shown), more than one of the vacuum suction holes may be separated from the vacuum workpiece handler 102 by non-zero distances. In some such embodiments, different ones of the restricting units (e.g., 111a-111c of FIG. 11A) may vary fluid communication between compromised vacuum suction holes and the shared vacuum plenum 112 by a same amount. In other such embodiments, different ones of the restricting units may vary fluid communication between compromised vacuum suction holes and the shared vacuum plenum 112 by different amounts. For example, in some embodiments different ones of the restricting units may reduce flow rates within the vacuum conduit 108 in a manner that causes a lower vacuum suction in areas of the semiconductor workpiece 208 that have a greater distance to the surface 104 and a higher vacuum suction in areas of the semiconductor workpiece 208 that have a smaller distance to the surface 104.

In some embodiments, the restricting units (e.g., 111a-111c of FIG. 11A) may comprise active restricting units. For example, the active restricting units may respectively comprise a blocking member 304 and an actuator 302 configured to vary a cross-sectional area of a vacuum conduit by changing a position of the blocking member within a vacuum conduit 108 in response to a signal generated by a controller 204. In other embodiments, the restricting units (e.g., 111a-111c of FIG. 11A) may comprise passive self-regulated restricting units. For example, the passive self-regulated restricting units may respectively comprise a diaphragm that is configured to vary a cross-sectional area of a vacuum conduit pneumatically.

As shown in top-view 1200, the semiconductor workpiece 208 is removed from the surface 104 of the vacuum workpiece handler 102. In some embodiments, the semiconductor workpiece 208 is removed from the surface 104 of the vacuum workpiece handler 102 by operating the vacuum source 116 to reduce a pressure within the shared vacuum plenum 112 and thus reduce the plurality of suction forces. Reducing the pressure within the shared vacuum plenum 112 reduces a flow rate to a final flow rate F_{F}.

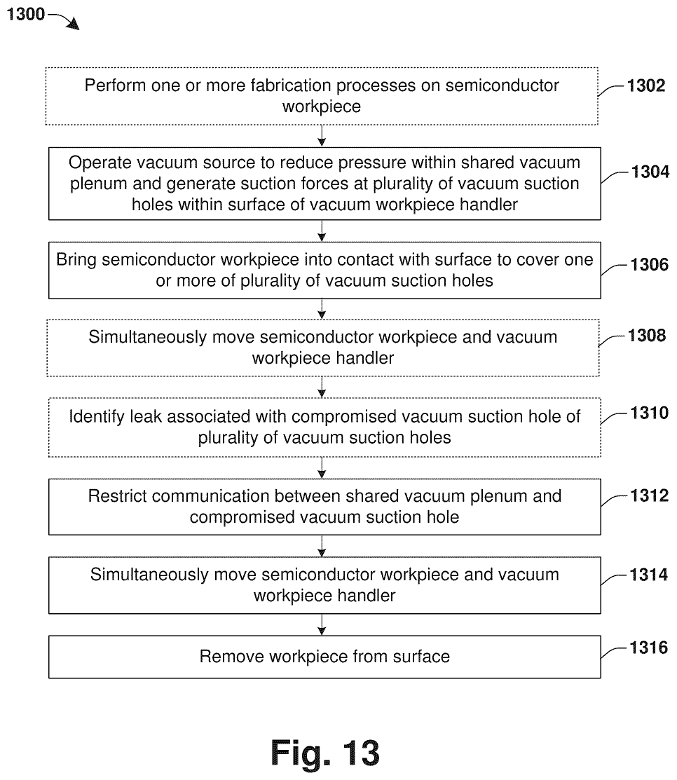

FIG. 13 illustrates some embodiments of method 1300 of operating a disclosed workpiece handling system to selectively restrict communication to one or more vacuum suction holes.

While method 1300 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases

At act 1302, one or more fabrication processes may be performed on a semiconductor workpiece. The one or more fabrication processes may cause (e.g., increase) a bowing of the semiconductor workpiece.

At act 1304, a vacuum source is operated to reduce a pressure within a shared vacuum plenum and to generate suction forces at a plurality of vacuum suction holes within a surface of a vacuum workpiece handler. FIG. 8 illustrates a top-view 800 of some embodiments corresponding to act 1304.

At act 1306, the semiconductor workpiece is brought into contact with the surface of the vacuum workpiece handler to cover one or more of the plurality of vacuum suction holes. FIG. 9 illustrates a top-view 900 of some embodiments corresponding to act 1306.

At act 1308, the semiconductor workpiece and the vacuum workpiece handler may be simultaneously moved in some embodiments.

At act 1310, a leak associated with a compromised vacuum suction hole of the plurality of vacuum suction holes may be identified, in some embodiments. FIG. 10 illustrates a top-view 1000 of some embodiments corresponding to act 1310.

At act 1312, fluid communication is restricted (e.g., fully or partially) between the shared vacuum plenum and the compromised vacuum suction hole. FIG. 10 illustrates a top-view 1000 of some embodiments corresponding to act 1312.

At act 1314, the semiconductor workpiece and the vacuum workpiece handler are simultaneously moved. Simultaneously moving the semiconductor workpiece and the vacuum workpiece handler allows for the vacuum workpiece handler to transport the semiconductor workpiece between different locations (e.g., between a wafer cassette and a processing tool).

At act 1316, the semiconductor workpiece is removed from the surface of the vacuum workpiece handler. FIG. 12 illustrates a top-view 1200 of some embodiments corresponding to act 1316.

Accordingly, the present disclosure relates to a workpiece handling system that is configured to mitigate an effect of compromised vacuum suction holes by varying communication (e.g., decreasing fluid communication) of a compromised vacuum suction hole with a vacuum system.

In some embodiments, the present disclosure relates to a workpiece handling system. The workpiece handling system includes a vacuum workpiece handler having a surface configured to receive a semiconductor workpiece, the surface including edges that form a plurality of vacuum suction holes along the surface; a plurality of vacuum conduits respectively coupled to the plurality of vacuum suction holes; a shared vacuum plenum coupled to the plurality of vacuum conduits, the plurality of vacuum conduits being arranged between the shared vacuum plenum and the plurality of vacuum suction holes; and a restrictor configured to independently vary communication of the plurality of vacuum conduits between the shared vacuum plenum and the plurality of vacuum suction holes, the restrictor including a plurality of self-regulated passive restricting units. In some embodiments, the restrictor is configured to restrict communication of a first vacuum conduit extending between the shared vacuum plenum and a first vacuum suction hole without varying communication of a second vacuum conduit extending between the shared vacuum plenum and a second vacuum suction hole. In some embodiments, the plurality of self-regulated passive restricting units are respectively configured to reduce communication of a single one of the plurality of vacuum conduits between the shared vacuum plenum and a single one of the plurality of vacuum suction holes. In some embodiments, the plurality of self-regulated passive restricting units respectively include a fixed-geometry structure. In some embodiments, the plurality of self-regulated passive restricting units are respectively configured to automatically vary communication between the shared vacuum plenum and a compromised vacuum suction hole of the plurality of vacuum suction holes upon formation of a leak in a vacuum of the shared vacuum plenum. In some embodiments, neighboring ones of the plurality of vacuum conduits respectively include fixed opposing sidewalls extending outward from the shared vacuum plenum in parallel to one another for a non-zero run length.

In other embodiments, the present disclosure relates to a workpiece handling system. The workpiece handling system includes a vacuum workpiece handler having an outer casing including a surface configured to receive a semiconductor workpiece; a plurality of vacuum conduits respectively coupled to a plurality of vacuum suction holes extending through the surface; a shared vacuum plenum connected to the plurality of vacuum suction holes by the plurality of vacuum conduits; and a plurality of restricting units in communication with a respective one of the plurality of vacuum conduits, the plurality of restricting units being configured to respectively reduce section at one or more compromised vacuum suction holes by reducing fluid communication between of the one or more compromised vacuum suction holes and the shared vacuum plenum. In some embodiments, the plurality of restricting units are arranged between the shared vacuum plenum and the plurality of vacuum suction holes. In some embodiments, the vacuum workpiece handler includes an end-effector; and a robot is coupled to the end-effector, the plurality of vacuum conduits, the shared vacuum plenum, and the plurality of restricting units being housed within the outer casing of the vacuum workpiece handler. In some embodiments, the vacuum workpiece handler includes an end-effector; and a robot coupled to the end-effector, at least a part of the plurality of vacuum conduits, the shared vacuum plenum, and the plurality of restricting units being housed outside of the outer casing of the vacuum workpiece handler. In some embodiments, the plurality of restricting units include diaphragm valves. In some embodiments, the workpiece handling system further includes one or more sensors arranged in communication with the plurality of vacuum conduits and configured to measure data within one or more of the plurality of vacuum conduits; and a controller configured to control operation of one or more of the plurality of restricting units based upon the data measured by the one or more sensors. In some embodiments, the one or more sensors include a pressure sensor or a flow rate sensor.

In yet other embodiments, the present disclosure relates to a method. The method includes operating a vacuum source to reduce a pressure within a shared vacuum plenum, reducing the pressure within the shared vacuum plenum generates suction forces at a plurality of vacuum suction holes within a surface of a vacuum workpiece handler; bringing a semiconductor workpiece into contact with the surface, the semiconductor workpiece covering one or more of the plurality of vacuum suction holes; restricting fluid communication between the shared vacuum plenum and a compromised vacuum suction hole of the plurality of vacuum suction holes to reduce a suction force generated by the compromised vacuum suction hole, a space being present between the semiconductor workpiece and the surface immediately surrounding the compromised vacuum suction hole; and removing the semiconductor workpiece from the surface of the vacuum workpiece handler. In some embodiments, the method further includes measuring data associated with a plurality of vacuum conduits coupled between the shared vacuum plenum and the plurality of vacuum suction holes; and identifying the compromised vacuum suction hole using the data. In some embodiments, the data includes one or more of a pressure or a flow rate within a vacuum conduit coupled between the compromised vacuum suction hole and the shared vacuum plenum. In some embodiments, the method further includes restricting fluid communication between the compromised vacuum suction hole and the shared vacuum plenum without varying fluid communication between other ones of the plurality of vacuum suction holes and the shared vacuum plenum. In some embodiments, the method further includes utilizing a diaphragm valve to automatically restrict fluid communication between the compromised vacuum suction hole and the shared vacuum plenum upon formation of a leak. In some embodiments, restricting fluid communication between the shared vacuum plenum and the compromised vacuum suction hole includes varying a cross-sectional area of a vacuum conduit coupled between the compromised vacuum suction hole and the shared vacuum plenum. In some embodiments, the compromised vacuum suction hole includes a vacuum suction hole that is not completely covered by the semiconductor workpiece.

Although the disclosure has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “including”, “has”, “having”, and variants thereof are used in either the detailed description or the claims, these terms are intended to be inclusive in a manner similar to the term “comprising”.

What is claimed is:

1. A workpiece handling system, comprising:
a vacuum workpiece handler having a surface configured to receive a semiconductor workpiece, wherein the surface comprises edges that form a plurality of vacuum suction holes along the surface;
a plurality of vacuum conduits respectively coupled to the plurality of vacuum suction holes;
a shared vacuum plenum coupled to the plurality of vacuum conduits, wherein the plurality of vacuum conduits are arranged between the shared vacuum plenum and the plurality of vacuum suction holes; and
a restrictor configured to independently vary communication of the plurality of vacuum conduits between the shared vacuum plenum and the plurality of vacuum suction holes, wherein the restrictor comprises a plurality of self-regulated passive restricting units.

2. The workpiece handling system of claim 1, wherein the restrictor is configured to restrict communication of a first vacuum conduit extending between the shared vacuum plenum and a first vacuum suction hole without varying communication of a second vacuum conduit extending between the shared vacuum plenum and a second vacuum suction hole.

3. The workpiece handling system of claim 1, wherein the plurality of self-regulated passive restricting units are respectively configured to reduce communication of a single one of the plurality of vacuum conduits between the shared vacuum plenum and a single one of the plurality of vacuum suction holes.

4. The workpiece handling system of claim 1, wherein the plurality of self-regulated passive restricting units respectively comprise a fixed-geometry structure.

5. The workpiece handling system of claim 1, wherein the plurality of self-regulated passive restricting units are respectively configured to automatically vary communication between the shared vacuum plenum and a compromised vacuum suction hole of the plurality of vacuum suction holes upon formation of a leak in a vacuum of the shared vacuum plenum.

6. The workpiece handling system of claim 1, wherein neighboring ones of the plurality of vacuum conduits respectively comprise fixed opposing sidewalls extending outward from the shared vacuum plenum in parallel to one another for a non-zero run length.

7. A workpiece handling system, comprising:
a vacuum workpiece handler having an outer casing comprising a surface configured to receive a semiconductor workpiece;
a plurality of vacuum conduits respectively coupled to a plurality of vacuum suction holes extending through the surface;
a shared vacuum plenum connected to the plurality of vacuum suction holes by the plurality of vacuum conduits; and
a plurality of restricting units in communication with a respective one of the plurality of vacuum conduits, wherein the plurality of restricting units are configured to respectively reduce suction at one or more compromised vacuum suction holes by reducing fluid communication between the one or more compromised vacuum suction holes and the shared vacuum plenum.

8. The workpiece handling system of claim 7, wherein the plurality of restricting units are arranged between the shared vacuum plenum and the plurality of vacuum suction holes.

9. The workpiece handling system of claim 7,
wherein the vacuum workpiece handler comprises an end-effector; and
wherein a robot is coupled to the end-effector, the plurality of vacuum conduits, the shared vacuum plenum, and the plurality of restricting units being housed within the outer casing of the vacuum workpiece handler.

10. The workpiece handling system of claim 7,
wherein the vacuum workpiece handler comprises an end-effector; and
wherein a robot coupled to the end-effector, at least a part of the plurality of vacuum conduits, the shared vacuum plenum, and the plurality of restricting units being housed outside of the outer casing of the vacuum workpiece handler.

11. The workpiece handling system of claim 7, wherein the plurality of restricting units comprise diaphragm valves.

12. The workpiece handling system of claim 7, further comprising:
one or more sensors arranged in communication with the plurality of vacuum conduits and configured to measure data within one or more of the plurality of vacuum conduits; and
a controller configured to control operation of one or more of the plurality of restricting units based upon the data measured by the one or more sensors.

13. The workpiece handling system of claim 12, wherein the one or more sensors comprise a pressure sensor or a flow rate sensor.

14. A method, comprising:
operating a vacuum source to reduce a pressure within a shared vacuum plenum, wherein reducing the pressure within the shared vacuum plenum generates suction forces at a plurality of vacuum suction holes within a surface of a vacuum workpiece handler;
bringing a semiconductor workpiece into contact with the surface, the semiconductor workpiece covering one or more of the plurality of vacuum suction holes;
restricting fluid communication between the shared vacuum plenum and a compromised vacuum suction hole of the plurality of vacuum suction holes to reduce a suction force generated by the compromised vacuum suction hole, wherein a space is present between the semiconductor workpiece and the surface immediately surrounding the compromised vacuum suction hole; and
removing the semiconductor workpiece from the surface of the vacuum workpiece handler.

15. The method of claim 14, further comprising:
measuring data associated with a plurality of vacuum conduits coupled between the shared vacuum plenum and the plurality of vacuum suction holes; and
identifying the compromised vacuum suction hole using the data.

16. The method of claim 15, wherein the data comprises one or more of a pressure or a flow rate within a vacuum conduit coupled between the compromised vacuum suction hole and the shared vacuum plenum.

17. The method of claim 14, further comprising:
restricting fluid communication between the compromised vacuum suction hole and the shared vacuum plenum without varying fluid communication between other ones of the plurality of vacuum suction holes and the shared vacuum plenum.

18. The method of claim 14, further comprising:
utilizing a diaphragm valve to automatically restrict fluid communication between the compromised vacuum suction hole and the shared vacuum plenum upon formation of a leak.

19. The method of claim 14, wherein restricting fluid communication between the shared vacuum plenum and the compromised vacuum suction hole comprises varying a cross-sectional area of a vacuum conduit coupled between the compromised vacuum suction hole and the shared vacuum plenum.

20. The method of claim 14, wherein the compromised vacuum suction hole comprises a vacuum suction hole that is not completely covered by the semiconductor workpiece.
